(19) United States
(12) Patent Application Publication
(10) Pub. No.: US 2025/0364487 A1
(43) Pub. Date: Nov. 27, 2025

(54) THREE-DIMENSIONAL SEMICONDUCTOR PACKAGE COMPONENT AND METHOD FOR MAKING THE SAME

(71) Applicant: Powertech Technology Inc., Hukou (TW)

(72) Inventors: Jen-I HUANG, Hukou (TW); Kun-Yung HUANG, Hukou (TW)

(73) Assignee: Powertech Technology Inc., Hukou (TW)

(21) Appl. No.: 19/203,732

(22) Filed: May 9, 2025

(30) Foreign Application Priority Data
May 22, 2024 (TW) 113118937

(51) Int. Cl. H01L 25/065; H01L 21/48; H01L 21/56; H01L 21/683; H01L 23/00; H01L 23/48; H01L 23/498; H01L 23/538; H01L 25/03; H10D 80/30

(52) U.S. Cl. CPC H01L 25/0655; H01L 21/4853; H01L 21/568; H01L 21/6835; H01L 23/49838; H01L 23/5385; H01L 24/16; H01L 25/03; H01L 23/481; H01L 24/04; H01L 2224/0401; H01L 2224/16227; H01L 2924/1815; H10D 80/30

(57) ABSTRACT

A three-dimensional (3D) semiconductor package component includes a carrier substrate, a first redistribution layer unit, at least one 3D packaging chip, an encapsulation layer and a second redistribution layer unit. The first redistribution layer unit is formed on a surface of the carrier substrate. The at least one 3D packaging chip is formed on the first redistribution layer unit. The encapsulation layer covers a surface of the first redistribution layer unit and encapsulates at least one 3D packaging chip. The second redistribution layer unit is formed on a surface of the encapsulation layer opposite to the first redistribution layer unit. A method for making the 3D semiconductor package component is also provided.

### CROSS-REFERENCE TO RELATED APPLICATION

This application claims priority to Taiwanese Invention patent application No. 113118937, filed on May 22, 2024, the entire disclosure of which is incorporated by reference herein.

### FIELD

The disclosure relates to a semiconductor package component and a method for making the same, and more particularly to a three-dimensional (3D) semiconductor package component and a method for making the same.

### BACKGROUND

Semiconductor packaging is an important step in semiconductor manufacturing process. With the advancement of semiconductor process technology, the density of transistors on a single chip has reached a limit. Therefore, in addition to continuing to develop advanced processes, skilled artisan are dedicated to increase the number of transistors on a single substrate through packaging technology so as to improve the performance, power consumption, heat dissipation, and other capabilities of the chip. Such approach is also the direction to be developed for those skilled in the art. Advanced packaging processes systematically integrate different die chips through 3D multi-layer stacking and connections to form final usable 3D integrated circuits.

In the flip-chip packaging commonly used in the packaging technology, solder bumps made of tin-lead are formed on bonding pads of an active surface of a chip used for packaging, allowing other bonding pads on the substrate used for packaging to be in positions corresponding to the solder bumps on the chip. After aligning the solder bumps with the bonding pads on the substrate, the solder bumps are melted and bonded to the bonding pads through reflow soldering, so as to create signal transmission paths between the chip and the substrate. Therefore, in order to ensure the success of flip-chip packaging technology so as to ensure proper signal transmission between the chip and another chip, the coplanarity of the bonding pads on the surface of the substrate which is bonded to the chip is an important factor for the success of the bonding process.

In a typical packaging process for connecting bottom package components to different chips, before connecting to the chips, a redistribution layer is usually formed on top surfaces of the bottom package components for circuit redistribution. Afterward, bonding pads for connecting the chips are formed on a top surface of the redistribution layer. However, since the redistribution layer is formed by stacking dielectric layers and circuit layers through a manufacturing process, the coplanarity of the bonding pads that are finally formed on the top surface of the redistribution layer for electrical connection with the chips may deteriorate, thereby affecting the yield of the bonding process. Therefore, improving the coplanarity of elements on the substrate (i.e., the coplanarity of the bonding pads) for bonding to the chips is also an important direction for those skilled in the art to continuously refine.

### SUMMARY

Therefore, an object of the disclosure is to provide a three-dimensional (3D) semiconductor package component and a method for making a three-dimensional (3D) semiconductor package component that can alleviate at least one of the drawbacks of the prior art.

According to a first aspect of the disclosure, the three-dimensional (3D) semiconductor package component includes a carrier substrate, a first redistribution layer unit, at least one 3D packaging chip, an encapsulation layer and a second redistribution layer unit. The first redistribution layer unit is formed on a surface of the carrier substrate. The at least one 3D packaging chip is formed on the first redistribution layer unit, and includes through holes and conductive pillars respectively filling in the through holes. Each of the conductive pillars is exposed from two opposite ends of a corresponding one of the through holes. The at least one 3D packaging chip is electrically connected to the first redistribution layer unit through the conductive pillars. The encapsulation layer covers a surface of the first redistribution layer unit and encapsulates the at least one 3D packaging chip such that surfaces of the conductive pillars, which are opposite to the first redistribution layer unit, are exposed from the encapsulation layer. The second redistribution layer unit is formed on a surface of the encapsulation layer opposite to the first redistribution layer unit. The second redistribution layer unit is electrically connected to the conductive pillars of the at least one 3D packaging chip, and includes connector pads exposed from a surface of a dielectric layer of the second redistribution layer unit which is opposite to the at least one 3D packaging chip. Each of the connector pads includes a metal inner core and a seed layer that is formed on a surface of the metal inner core. The seed layer is made of a material different from a material of the metal inner core and is exposed for electrical connection.

According to a second aspect of the disclosure, the method for making the three-dimensional (3D) semiconductor package component includes the steps of:
A) forming one redistribution layer unit on a surface of a first substrate, the one redistribution layer unit including
   one dielectric layer that is formed on the surface of the first substrate and that defines openings, and
   connector pads respectively located in the openings and connected to the first substrate;
B) preparing and disposing at least one three-dimensional packaging chip on the one redistribution layer unit, the at least one 3D packaging chip including through holes and conductive pillars respectively filling in the through holes, the at least one 3D packaging chip being electrically connected to the connector pads of the one redistribution layer unit through the conductive pillars;
C) forming an encapsulation layer which covers the surface of the first substrate and which encapsulates the at least one 3D packaging chip, such that surfaces of the conductive pillars of the at least one 3D packaging chip, which are opposite to the one redistribution layer unit, are exposed outwardly from the encapsulation layer, a surface of the encapsulation layer being coplanar with an exposed surface of the at least one 3D packaging chip, so as to cooperatively define a top surface;
D) forming another redistribution layer unit on the top surface, the another redistribution layer unit including another dielectric layers and circuit layers which are formed in an alternate manner, the another redistribution layer unit being electrically connected to the at least one 3D packaging chip; and
E) disposing a carrier substrate on a surface of the another redistribution layer unit opposite to the one redistribution layer unit, and removing the first substrate such that the connector pads of the one redistribution layer unit are exposed outwardly.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic cross-sectional view illustrating a three-dimensional (3D) semiconductor package component according to an embodiment of the disclosure.

FIG. 2 is a partially fragmentary and enlarged view for assisting in illustration of FIG. 1.

FIG. 3 is a flow chart illustrating a method for making the 3D semiconductor package component according to an embodiment of the disclosure.

FIGS. 4 to 6 are schematic views illustrating consecutive steps in the method for making the 3D semiconductor package component.

FIG. 7 is a partially fragmentary and enlarged view of a second redistribution layer unit shown in (a) of FIG. 4.

FIG. 8 is a schematic view illustrating different structural configurations of a 3D packaging chip.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

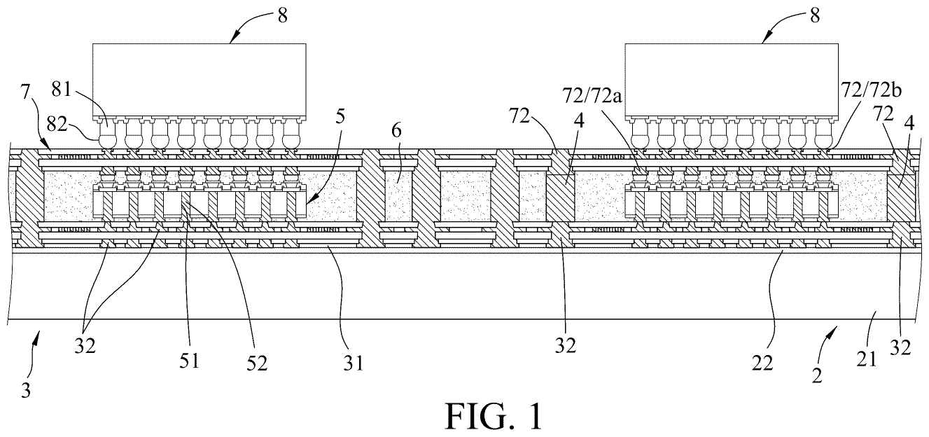

Referring to FIG. 1, a sectional side view of a three-dimensional (3D) semiconductor package component according to an embodiment of the present disclosure is shown.

The 3D semiconductor package component according to the embodiment of the present disclosure is a fan-out package component, and includes a carrier substrate 2, a first redistribution layer unit 3, conductive copper pillars 4, at least one 3D packaging chip 5, an encapsulation layer 6, a second redistribution layer unit 7, and at least one chip 8. In FIG. 1, two of the 3D packaging chips 5 are shown.

The carrier substrate 2 has a substrate 21, such as a glass substrate 21 as a carrier, and an adhesive layer 22 formed on a surface of the carrier substrate 21. When exposed to irradiation or heat, the adhesion of the adhesive layer 22 is weakened and/or removed.

The first redistribution layer unit 3 is formed on a surface of the carrier substrate 2. To be specific, the first redistribution layer unit 3 is formed on a surface of the adhesive layer 22, and has a first redistribution layer structure 31 and connector pads 32.

Specifically, the first redistribution layer structure 31 is formed by stacking first dielectric layers (not shown in the figure) made of a dielectric insulating material and first circuit layers (not shown in the figure) made of a conductive material. The first redistribution layer structure 31 is used to redistribute electrical connection positions. The connector pads 32 are electrically connected to the first redistribution layer structure 31 (e.g., the connector pads 32 are electrically connected to the first circuit layers of the first redistribution layer structure 31). The connector pads 32 are exposed from the first dielectric layers located at two opposite surfaces of the first redistribution layer structure 31 for external electrical connection. The dielectric insulating material may be selected from polyimide (PI), and the conductive material may be selected from Cu, Cu/Ni/Au, Cu/Ni/Sn or Cu/Ni/SnAg, etc. Since the selection of material and related structures of the first redistribution layer unit 3 are well-known in the art, details thereof are not described further.

The conductive copper pillars 4 are respectively located on some of the connector pads 32 and extend away from the carrier substrate 2.

The 3D packaging chips 5 utilize systematic integration of different die chips through 3D multi-layer stacking and connections, to thereby form a final usable 3D integrated circuits. Each of the 3D packaging chips 5 is formed and located on the first redistribution layer unit 3, and includes through holes 51 and conductive pillars 52 respectively filling in the through holes 51. Each of the conductive pillars 52 is exposed from two opposite ends of a corresponding one of the through holes 51. Moreover, each of the 3D packaging chips 5 is electrically connected to corresponding ones of the connector pads 32 of the first redistribution layer unit 3 through the conductive pillars 52. In this embodiment, two of the 3D packaging chips 5 are exemplified. However, in actual implementation, the number of the 3D packaging chips 5 is not limited to such number.

The encapsulation layer 6 is made of an encapsulating material selected from, such as an epoxy resin. The encapsulation layer 6 covers a surface of the first redistribution layer unit 3, and encapsulates the 3D packaging chips 5 so that electrical connecting surfaces of the conductive pillars 52 of each of the 3D packaging chips 5 and electrical connecting surfaces of the conductive copper pillars 4, which are opposite to the first redistribution layer unit 3, are exposed from the encapsulation layer 6.

The second redistribution layer unit 7 is formed on a surface of the encapsulation layer 6 opposite to the first redistribution layer unit 3. The second distribution layer unit 7 is electrically connected to the conductive pillars 52 of the 3D packaging chips 5. In addition, two opposite ends of each of the conductive copper pillars 4 are electrically connected to the first redistribution layer unit 3 and the second redistribution layer unit 7, respectively.

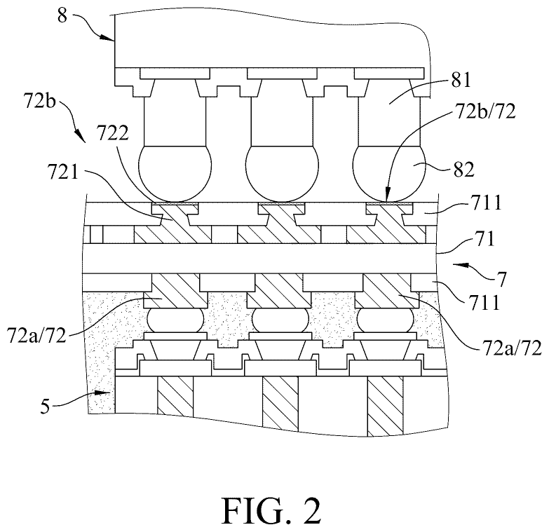

Specifically, reference is made to FIG. 2, which is a partially fragmentary and enlarged view of the second redistribution layer unit 7 in FIG. 1. The second redistribution layer unit 7 includes a second redistribution layer structure 71 and connector pads 72 for external electrical connection. The connector pads 72 are exposed from two opposite surfaces of the second redistribution layer structure 71. The second redistribution layer structure 71 is obtained by stacking second dielectric layers (not shown in the figure) and second circuit layers (not shown in the figure) so as to redistribute electrical connection positions. FIG. 2 only illustrates two dielectric layers 711 located at two opposite outermost surfaces of the second redistribution layer structure 71. The connector pads 72 are exposed respectively from the dielectric layers 711 and are electrically connected to the second circuit layers of the second redistribution layer structure 71. Some of the connector pads 72 (denoted as 72a), which are exposed from one of the dielectric layers 711 of the second redistribution layer structure 71 that is adjacent to the 3D packaging chips 5, are electrically connected to 3D packaging chip and the conductive pillars 52 of the 3D packaging chips 5; and some other of the connector pads 72 (denoted as 72b), which are exposed from a surface of other one of the dielectric layers 711 of the second redistribution layer structure 71 that is opposite to the 3D packaging chips 5, are for external electrical connection. In the second redistribution layer unit 7, a dielectric insulating material of the second dielectric layers, and a conductive material of the second circuit layers for electrical connection may be selected from the dielectric insulating material of the first dielectric layers and the conductive material of the first circuit layers described above for the first redistribution layer unit 3, respectively, and thus will not be described in detail. In particular, referring again to FIG. 2, the connector pads 72a may be formed by deposition of a single electrically conductive material. Each of the connector pads 72b includes a metal inner core 721 and a seed layer 722 that is formed on a surface of the metal inner core 721. The seed layer 722 is made of a material different from a material of the metal inner core 721. The seed layer 722 is flush with the surface of the adjacent one of the dielectric layer 711 and is exposed for electrical connection with the chip 8.

The chip 8 is electrically connected to the second redistribution layer unit 7 in a flip-chip manner.

Specifically, the chip 8 has bonding pads 81 and solder balls 82 respectively formed on the bonding pads 81, and is electrically connected to the connector pads 72b through the solder balls 82. In other words, the chip 8 is connected to the connector pads 72b by flip-chip technique.

The manufacturing method of the embodiment of the 3D semiconductor package component is described as follows.

The manufacturing method of the embodiment of the 3D semiconductor package component includes the following steps.

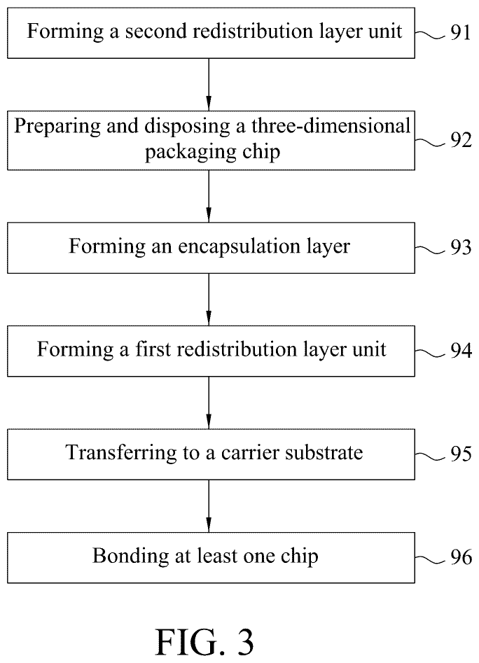

Referring to FIGS. 1, 3 and 4, step 91 of forming one redistribution layer unit (i.e., the second redistribution layer unit 7) is first performed. A first substrate 100 is provided, and the second redistribution layer unit 7 and the conductive copper pillars 4 are formed on a surface of the first substrate 100. The first substrate 100 includes a substrate 101 made of glass and an adhesive layer 102 formed on a surface of the substrate 101. When exposed to irradiation or heat, the adhesion of the adhesive layer 102 is weakened and/or removed.

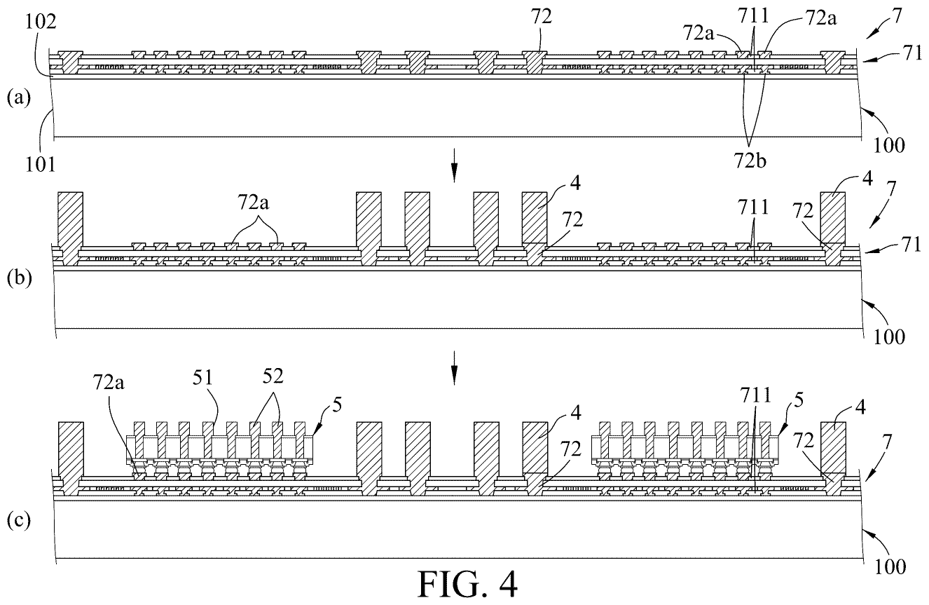

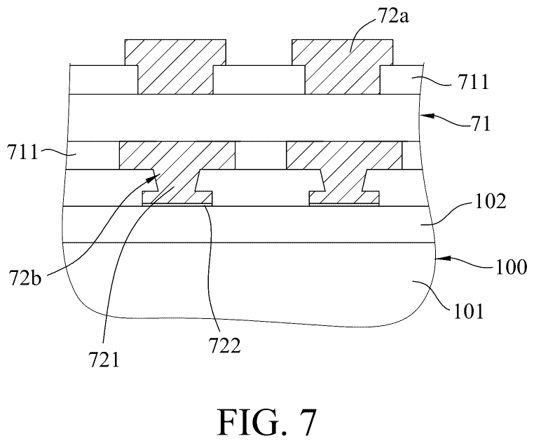

Specifically, reference is further made to FIG. 7, which is a partially fragmentary and enlarged view of the second redistribution layer unit 7 shown in (a) of FIG. 4. In step 91 of forming the second redistribution layer unit 7, a deposition process and a photolithography processes are first utilized to form one dielectric layer (i.e., one of the dielectric layers 711) which defines openings on the surface of the first substrate 100 to expose the surface of the first substrate 100. Then, the seed layer 722 is formed and located in a corresponding one of the openings, and is connected to the first substrate 100. Thereafter, the metal inner core 721 is deposited on the seed layer 722, thereby completing the fabrication of the connector pads 72b which are respectively located in the corresponding one of the openings and connected to the first substrate 100. The material of the seed layer 722 may be selected from Cu, and the material of the metal inner core 721 may be selected from Ti/Cu, TiW/Cu, TiN/Cu, or Cu.

Then, multiple layers of the alternately stacked second dielectric layers (not shown in the figure) and second circuit layers (not shown in the figure) are formed on the one of the dielectric layers 711 and the connector pads 72b to obtain the second redistribution layer structure 71 and the connector pads 72a. The second redistribution layer structure 71 is electrically connected to the connector pads 72a. The connector pads 72a are exposed from the surface of the other one of the dielectric layers 711 of the second redistributed circuit structure 71 that is opposite to the connector pads 72b. In addition, the conductive copper pillars 4 are formed on some of the connector pads 72a and extend away from the first substrate 100, thereby obtaining the structure as shown in (b) of FIG. 4. Since structures, materials, and related manufacturing process of the conductive copper pillars 4 and the redistribution layer structure are well-known in the art, a detailed description thereof is omitted herein.

Then, step 92 of preparing and disposing the 3D packaging chips 5 is performed. Each of the 3D packaging chips 5 is obtained by subjecting chips (not shown in the figure) to 3D packaging, and includes the through holes 51 and the conductive pillars 52 respectively filling in the through holes 51. In step 92, the 3D packaging chips 5 are disposed on the second redistribution layer unit 7, and are electrically connected to the connector pads 72a of the second redistribution layer unit 7 through the conductive pillars 52, so as to obtain the structure shown in (c) of FIG. 4.

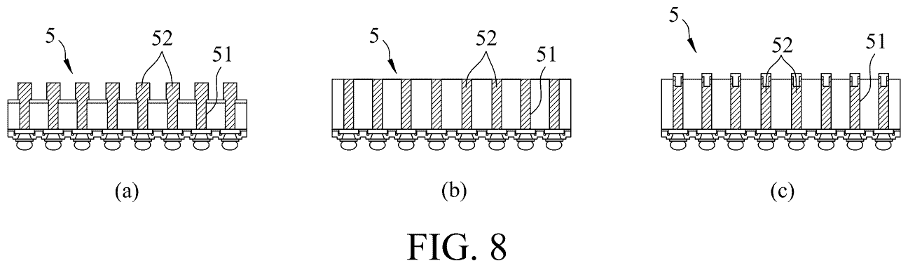

Referring to FIG. 8, one end of each of the conductive pillars 52 of the 3D packaging chips 5, which is opposite to the second redistribution layer unit 7, may protrude from a corresponding one of the through holes 51 (see (a) of FIG. 8), be flush with the corresponding one of the through holes 51 (see (b) of FIG. 8), or be indented within the corresponding one of the through holes 51 (see (c) of FIG. 8).

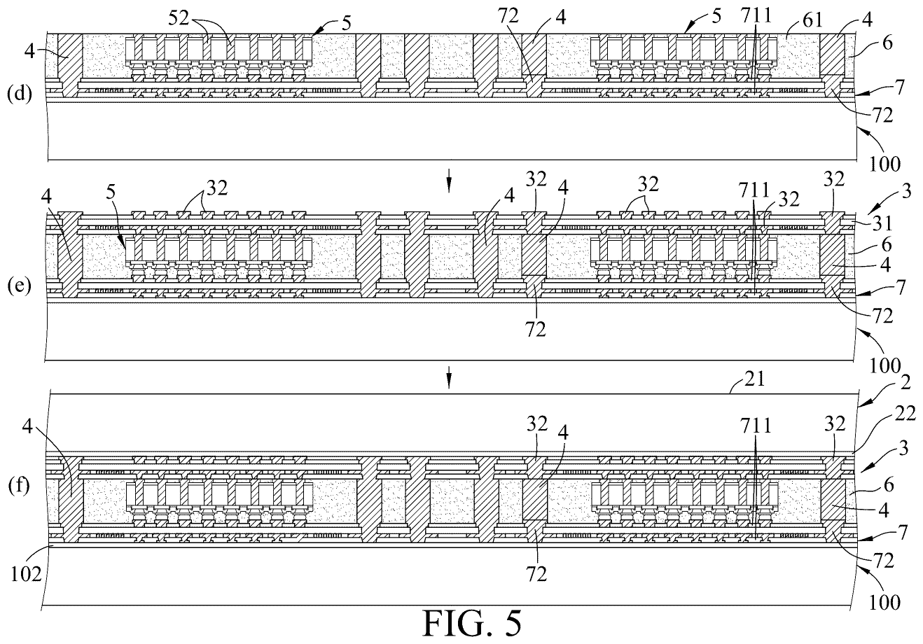

Then, step 93 of forming the encapsulation layer 6 is performed to form the encapsulation layer 6 covering a surface of the first substrate 100 and encapsulating a periphery of each of the 3D packaging chips 5, such that the surfaces of the conductive pillars 52 of the 3D packaging chips 5 opposite to the second redistribution layer unit 7 are exposed outwardly from the encapsulation layer 6, and the surface of the encapsulation layer 6 and exposed surfaces of the 3D packaging chips 5 are coplanar to cooperatively define a top surface 61, thereby obtaining the structure shown in (d) of FIG. 5.

Specifically, in step 93, an encapsulant is firstly formed to cover the surface of the first substrate 100 and to encapsulate the 3D packaging chips 5, and then a surface of the encapsulant opposite to the second redistribution layer unit 7 is subjected to a planarization process (e.g., a polishing process) to remove a portion of the encapsulant until the conductive copper pillars 4 and the conductive pillars 52 are planarized and exposed, so as to obtain the encapsulation layer 6. In other words, the conductive copper pillars 4 is also encapsulated by the encapsulant, and thus by the encapsulation layer 6. A surface of each of the conductive copper pillars 4 is exposed from the encapsulation layer 6, and is coplanar with the surface of the encapsulation layer 6 and the surfaces of the 3D packaging chips 5, so as to define the top surface 61.

Then, step 94 of forming another redistribution layer unit (i.e., the first redistribution layer unit 3) is performed. The first redistribution layer unit 3 is formed on the top surface 61 of the encapsulation layer 6 by alternately stacking another dielectric layers (i.e., the first dielectric layers, not shown in the figure) and circuit layers (i.e., the first circuit layers, not shown in the figure), so as to obtain the structure shown in (e) of FIG. 5. The first redistribution layer unit 3 includes the first redistribution layer structure 31 and the connector pads 32. The first redistribution layer structure 31 includes the first dielectric layers and the first circuit layers. The connector pads 32 are exposed outwardly from a surface of one of the first dielectric layers in the first redistribution layer structure 31 that is opposite to the 3D packaging chips 5. The connector pads 32 of the first redistribution layer unit 3 are electrically connected to the conductive copper pillars 4 and the conductive pillars 52 of the 3D packaged chips 5. The formation of the first redistribution layer unit 3 is similar to that of the second redistribution layer unit 7, except that each of the connector pads 32 of the first redistribution layer unit 3 may not need to be formed with the seed layer 722, and therefore is not described in detail.

Thereafter, step 95 is performed to transfer the structure on the first substrate 100 to the carrier substrate 2. Firstly, the carrier substrate 2 including the adhesive layer 22 is disposed on the surface of the first redistribution layer unit 3 opposite to the second redistribution layer unit 7, so as to obtain the structure shown in (f) of FIG. 5.

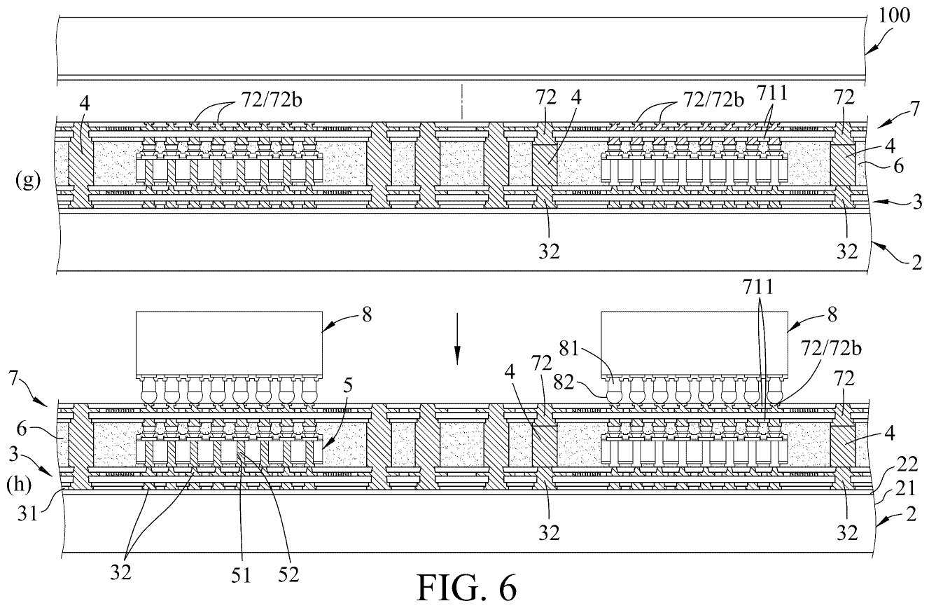

Then, based on the characteristic of the adhesive layer 102 (i.e., the adhesion of which is weakened and/or removed when exposed to irradiation or heat), the first substrate 100 is removed by utilizing irradiation or heating. Thus, the connector pads 72 (72b) of the second redistribution layer unit 7 are exposed outwardly, so as to obtain the structure shown in (g) of FIG. 6. To be specific, after removal of the first substrate 100, the seed layer 722 of each of the connector pads 72 of the second redistribution layer unit 7 is exposed outwardly.

Finally, step 96 is performed to bond the chip 8 to the connector pads 72b of the second redistribution layer unit 7 in a flip-chip manner, thereby obtaining the structure shown in (h) of FIG. 6.

Referring to the above, the chip 8 has the bonding pads 81 and the solder balls 82 respectively formed on the bonding pads 81. Step 96 involves connecting the chip 8 and the connector pads 72b of the second redistribution layer unit 7 through the solder balls 82, thereby completing the fabrication of the 3D semiconductor package component.

Conventionally, connector pads for connection with a chip are formed on a surface of a structure (e.g., a redistribution layer) after formation of the structure. Therefore, the conventional connector pads may have poor coplanarity, which may cause failure in subsequent flip-chip packaging processes. In contrast to the above, in the 3D semiconductor package component according to the present disclosure, the connector pads 72 (72b) that are connected to the chip 8 are allowed to be initially formed on the surface of the first substrate 100. Since the connector pads 72b are not formed on the surface of the redistribution layer (the second redistribution layer 7) through multiple manufacturing processes, and since coplanarity of the connector pads 72b can be maintained by using the original first substrate 100, flatness difference between the connector pads 72b can be controlled to be less than 5 μm, i.e., having excellent coplanarity, which can be more beneficial to improving yield of subsequent flip-chip packaging processes for bonding of the connector pads 72b to the chip 8. Moreover, in the 3D semiconductor package component, the chips encapsulated by the encapsulation layer 6 are the 3D packaging chips 5 each having through holes 51 (Through-Silicon Via (TSV)). Therefore, each of the conductive pillars 52 in the corresponding one of the through holes 51 can be utilized as conductive paths, so that the internal connection path is shorter, which can increase the transmission speed, and reduce the noise, thereby improving the integrity of the signal transmission and the integrity of power. Furthermore, since surfaces of the connector pads 72b exposed to the outside are the seed layers 722 thereof, adhesion to the solders may be further improved through the seed layer 722, and bonding strength of the connector pads 72b with the chip 8 is increased. Therefore, the purpose of the disclosure can be achieved indeed.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A three-dimensional (3D) semiconductor package component, comprising:
a carrier substrate;
a first redistribution layer unit formed on a surface of said carrier substrate;
at least one 3D packaging chip formed on said first redistribution layer unit, said at least one 3D packaging chip including through holes and conductive pillars respectively filling in said through holes, each of said conductive pillars being exposed from two opposite ends of a corresponding one of said through holes, said at least one 3D packaging chip being electrically connected to said first redistribution layer unit through said conductive pillars;
an encapsulation layer covering a surface of said first redistribution layer unit, said encapsulation layer encapsulating said at least one 3D packaging chip such that surfaces of said conductive pillars, which are opposite to said first redistribution layer unit, are exposed from said encapsulation layer; and
a second redistribution layer unit formed on a surface of said encapsulation layer opposite to said first redistribution layer unit, said second redistribution layer unit being electrically connected to said conductive pillars of said at least one 3D packaging chip, said second redistribution layer unit including connector pads exposed from a surface of a dielectric layer of said second redistribution layer unit which is opposite to said at least one 3D packaging chip, each of said connector pads including a metal inner core and a seed layer that is formed on a surface of said metal inner core, said seed layer being made of a material different from a material of said metal inner core and being exposed for electrical connection.

2. The 3D semiconductor package component as claimed in claim 1, further comprising at least one chip that is connected to the connector pads by flip-chip technique.

3. The 3D semiconductor package component as claimed in claim 1, further comprising conductive copper pillars, two opposite ends of each of said conductive copper pillars being electrically connected to said first redistribution layer unit and said second redistribution layer unit, respectively.

4. A method for making a three-dimensional (3D) semiconductor package component, comprising the steps of:
A) forming one redistribution layer unit on a surface of a first substrate, the one redistribution layer unit including
one dielectric layer that is formed on the surface of the first substrate and that defines openings, and
connector pads respectively located in the openings and connected to the first substrate;
B) preparing and disposing at least one three-dimensional packaging chip on the one redistribution layer unit, the at least one 3D packaging chip including through holes and conductive pillars respectively filling in the through holes, the at least one 3D packaging chip being electrically connected to the connector pads of the one redistribution layer unit through the conductive pillars;
C) forming an encapsulation layer which covers the surface of the first substrate and which encapsulates the at least one 3D packaging chip, such that surfaces of the conductive pillars of the at least one 3D packaging chip, which are opposite to the one redistribution layer unit, are exposed outwardly from the encapsulation layer, a surface of the encapsulation layer being coplanar with an exposed surface of the at least one 3D packaging chip, so as to cooperatively define a top surface;
D) forming another redistribution layer unit on the top surface, the another redistribution layer unit including another dielectric layers and circuit layers which are formed in an alternate manner, the another redistribution layer unit being electrically connected to the at least one 3D packaging chip; and
E) disposing a carrier substrate on a surface of the another redistribution layer unit opposite to the one redistribution layer unit, and removing the first substrate such that the connector pads of the one redistribution layer unit are exposed outwardly.

5. The method as claimed in claim 4, wherein:
in step A), each of the connector pads of the one redistribution layer unit includes
a seed layer that is located in a corresponding one of the openings, and connected to the first substrate, and
a metal inner core that is formed on a surface of the seed layer; and
in step E), the first substrate is removed such that the seed layer of each of the connector pads of the one redistribution layer unit is exposed outwardly.

6. The method as claimed in claim 4, wherein:
step A) further includes forming conductive copper pillars, the conductive copper pillars being connected to some of the connector pads and extending away from the first substrate; and
in step C), the encapsulation layer further encapsulates the conductive copper pillars, a surface of each of the conductive copper pillars being exposed from the encapsulation layer, and being coplanar with the surface of the encapsulation layer and the surface of the at least one 3D packaging chip, so as to define the top surface.

7. The method as claimed in claim 4, wherein in step C), an encapsulant is first formed to cover the surface of the first substrate and to encapsulate the at least one 3D packaging chip, and then a surface of the encapsulant which is opposite to the one redistribution layer unit is subjected to a planarization process, so as to obtain the encapsulation layer.

8. The method as claimed in claim 4, wherein in step B), one end of each of the conductive pillars, which is opposite to the one redistribution layer unit, protrudes from a corresponding one of the through holes, is flush with the corresponding one of the through holes, or is indented within the corresponding one of the through holes.

9. The method as claimed in claim 4, further comprising a step F) of bonding at least one chip to the connector pads of the one redistribution layer unit by a flip-chip technique.
